(19) United States
(12) Patent Application Publication
(10) Pub. No.: US 2006/0108917 A1
(43) Pub. Date: May 25, 2006

(54) Organic electroluminescent device and fabricating method thereof

(75) Inventor: Jun-Wen Chung, Tainan County (TW)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: CHI MEI OPTOELECTRONICS CORP., Tainan County (TW)

(21) Appl. No.: 11/245,160

(22) Filed: Oct. 7, 2005

(30) Foreign Application Priority Data
Oct. 8, 2004 (TW) 09130673

(51) Int. Cl. H01L 51/00

(52) U.S. Cl. 313/504

(57) ABSTRACT

An organic electroluminescent device includes a reflective metal layer, a transparent conductive layer, an organic emission layer, and an electrode, such as a cathode. The transparent conductive layer defines at least part of another electrode, such as an anode, and is formed above and electrically connected to the reflective metal layer. The organic emission layer is formed above the transparent conductive layer. The cathode is formed above the organic emission layer.

This application claims the benefit of Taiwan Application Serial No. 093130673, filed Oct. 08, 2004, the entirety of which is incorporated herein by reference.

### TECHNICAL FIELD

The disclosure relates in general to an emitting device, and more particularly, to an organic electroluminescent device (OELD), an organic electroluminescent display using the device and a method for fabricating the same.

### BACKGROUND

Organic electroluminescent devices (OELDs) have been known to be applicable to various types of flat displays, due to advantages such as self-emissiveness, thin form, high luminance, high luminous efficiency, high contrast, fast response time, wide viewing angle, low power consumption, wide temperature operation range, and potential flexibility.

Refer to FIG. 1, which is a cross sectional view of the conventional organic electroluminescent device. The conventional organic electroluminescent device 100 includes a conductive layer 10, a work function layer 11, an organic emission layer (OEL) 12, and a cathode 13. The work function layer 11 is formed on the conductive layer 10. The conductive layer 10 and the work function layer 11 are combined to be a complex anode. The organic emission layer 12 is disposed on the work function layer 11, and the cathode 13 is disposed on the organic emission layer 12. Conventionally, the conductive layer 10 consists of a transparent oxide, such as indium tin oxide (ITO). In the conventional fabricating process, after the ITO is deposited, the ITO must be re-crystallized through an annealing process in order to decrease the resistance and improve the conductivity. However, the conductive layer 10, i.e., re-crystallized ITO, exhibits an inherently uneven surface. The work function layer 11 and the organic emission layer 12, sequentially disposed on the conductive layer 10, are inherently uneven due to the uneveness of the conductive layer 10. This may result in various defects in the fabricated OELD, and also deteriorates the performance of the OELD.

Refer to FIG. 2, which is a cross sectional view of another conventional organic electroluminescent device (OELD). The conventional OELD 200 includes a metal layer 20, a work function layer 21, an organic emission layer 22 and a cathode 23. The aforementioned conductive layer 10 is replaced by the metal layer 20 having a smooth surface and high reflectivity in the OELD 200. The metal layer 20 reflects the light emitted from the organic emission layer 22 toward the viewer in order to increase the luminance efficiency of the OELD 200. In the conventional fabricating process, the work function layer 21 is formed on the metal layer 20, preferably aluminum or silver, and then a partition insulating layer and a partition rib are formed on a part of the work function layer 21 by a photolithography process to define a pixel region. In the photolithography process, it is noted that a stripper, such as organic or inorganic alkali, is usually used for removing the photoresist layer. At least, an organic emission layer 22 and a cathode 23 are sequentially formed on the work function layer 21.

However, if the metal layer is made of aluminum (Al), the work function layer 21 is so flimsy (about 50 Å thick) that the metal layer 20 is subject to erosion caused by the stripper. This has a negative influence on the reflectivity of the metal layer 20. In addition, if the metal layer 20 is made of silver (Ag), silver atoms will gradually diffuse to the work function layer 21 during operation of OELD 200, and the work function layer will be unsatisfactory for its original function.

Thus, an organic electroluminescent device (OELD) and a fabricating method thereof are required in order to not only improve the conductivity of the anode but also protect the reflective metal layer from erosion.

### SUMMARY

In accordance with an aspect, an organic electroluminescent device includes a reflective metal layer and a transparent conductive layer together defining a first electrode, an organic emission layer, and a second electrode. The transparent conductive layer, as main part of the first electrode, is formed above and electrically connected to the reflective metal layer. The organic emission layer is formed above the transparent conductive layer. The cathode is formed above the organic emission layer.

In accordance with another aspect, a method of fabricating an organic electroluminescent device (OELD), comprises the steps of: forming a first electrode comprising a transparent conductive layer formed on and electrically connected to a reflective metal layer; forming an organic emission layer above the transparent conductive layer; and forming a second electrode above the organic emission layer.

In accordance with a further aspect, an organic electroluminescent display comprises an organic electroluminescent device (OELD) which, in turn, comprises a reflective metal layer; a transparent conductive layer formed above and electrically connected to the reflective metal layer to define a first electrode; an organic emission layer formed above the transparent conductive layer; and a second electrode formed above the organic emission layer.

Objects, features, and advantages of disclosed embodiments of the invention will become apparent from the following detailed description of such non-limiting embodiments. The following description is made with reference to the accompanying drawings.

### BRIEF DESCRIPTION OF THE DRAWINGS

FIG. 1 is a cross sectional view of the conventional organic electroluminescent device (OELD).

FIG. 2 is a cross sectional view of another conventional organic electroluminescent device.

FIG. 3 is a diagram of an organic electroluminescent device (OELD) according to an embodiment of the invention.

FIGS. 4A-4L are diagrams illustrating a method for fabricating OELDs according to an embodiment of the invention.

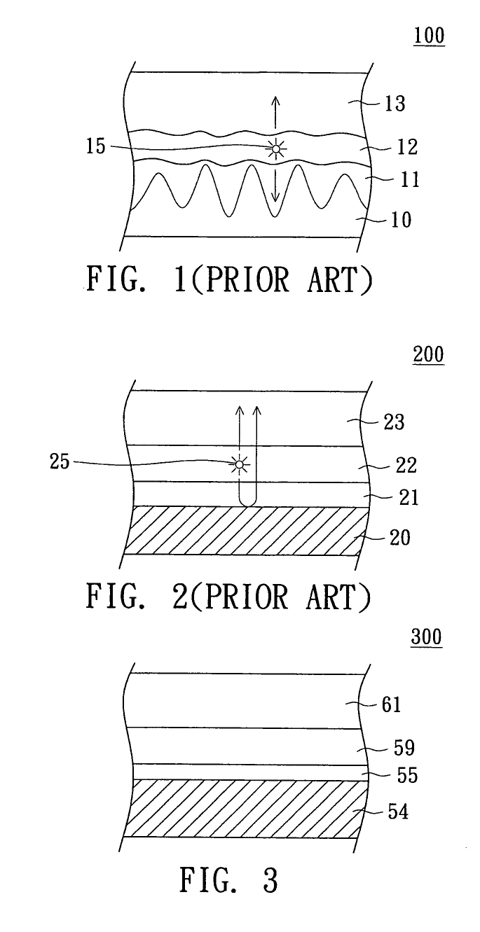

### DETAILED DESCRIPTION OF EMBODIMENTS

Disclosed embodiments of the present invention now will be described with reference to the accompanying drawings. This invention can, however, be embodied in many different forms and .should not be construed as limited to the embodiments set forth herein; rather, these embodiments are provided so that this disclosure will be thorough and complete, and will fully convey the scope of the invention to those skilled in the art. Like numbers refer to like components throughout.

The organic electroluminescent device (OELD) in accordance with an embodiment of the invention comprises a transparent conductive layer, which need not be formed by an annealing process as observed in the art, which is electrically connected to a reflective metal layer, and which covers the reflective metal layer to prevent the reflective metal layer from being eroded by a stripper usually used in fabrication of OELDs, and/or to prevent the atoms in the reflective metal layer from diffusing to an adjacent work function layer. Such OELD, in accordance with a further embodiment, can be used in an organic electroluminescent display which further comprises one or more components known in the art, such as supporting substrates, driving circuits etc.

Refer now to FIG. 3, which is a diagram of an organic electroluminescent device (OELD) according to an embodiment of the invention. The OELD 300 of this embodiment at least includes a reflective metal layer 54, a transparent conductive layer 55, an organic emission layer 59, and an electrode, e. g, a cathode 61. The transparent conductive layer 55, as a main part of another electrode, such as an anode, is formed above and electrically connected to the reflective metal layer 54. The organic emission layer 59 is formed above the transparent conductive layer 55, and the cathode 61 is formed above the organic emission layer 59.

Other, additional components can be added to basic structure described above depending on application. An active matrix top-emission type OELD, with a reflective metal layer positioned below the organic emission layer in order to reflect the emitted light toward the top of the device and toward the viewer, and a method of fabricating the same will now be described as a specific embodiment of the invention which is, however, is not limited to such specific embodiment. For example, the OELD in accordance with another embodiment of the invention could be a passive matrix OELD, or a bottom-emission type OELD with a reflective metal layer positioned above the organic emission layer.

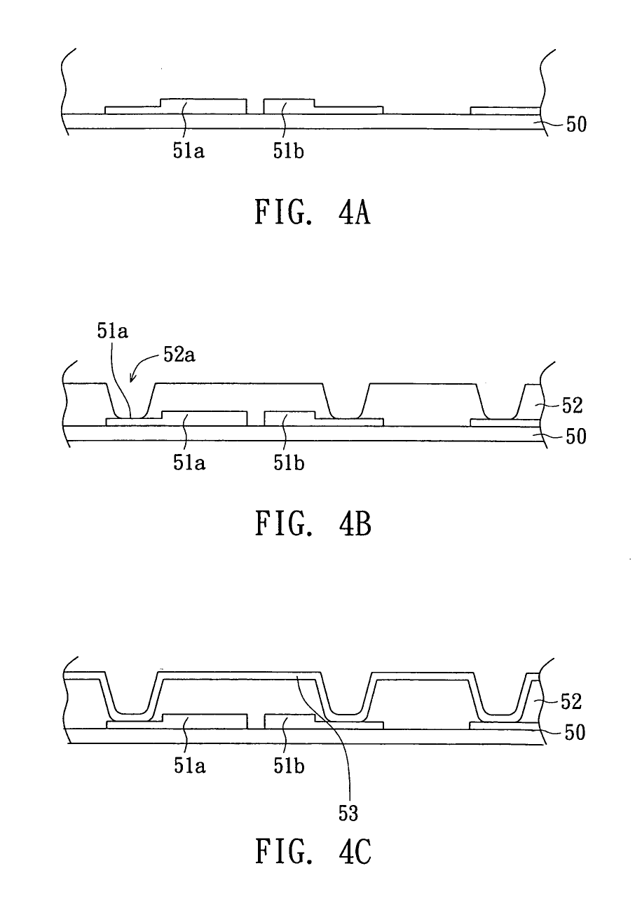

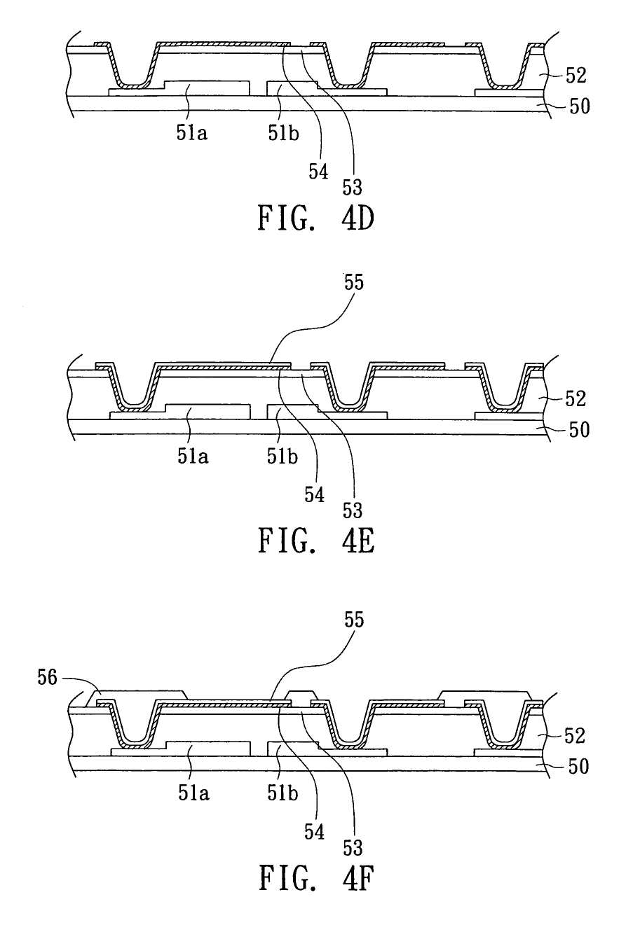

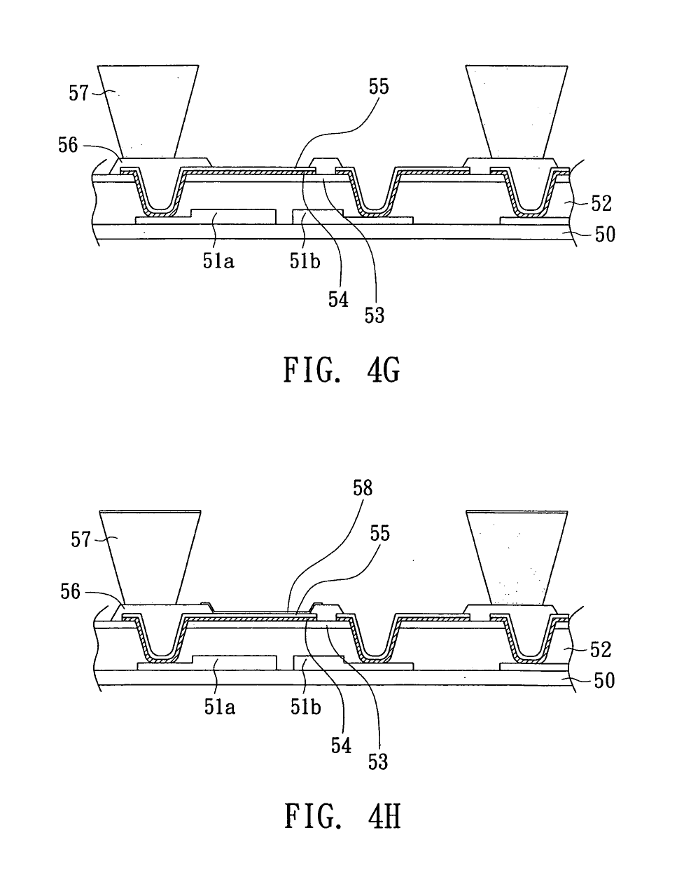

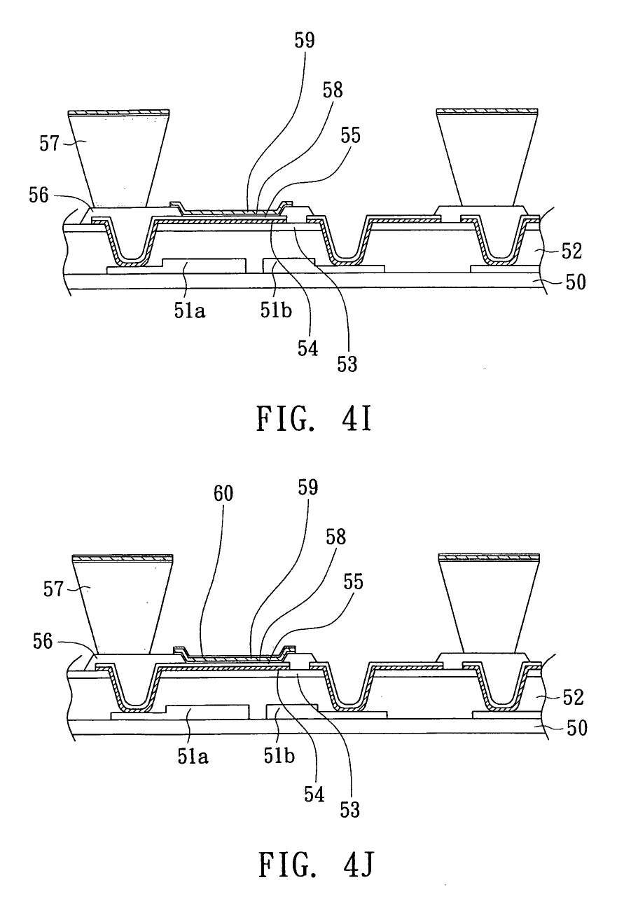

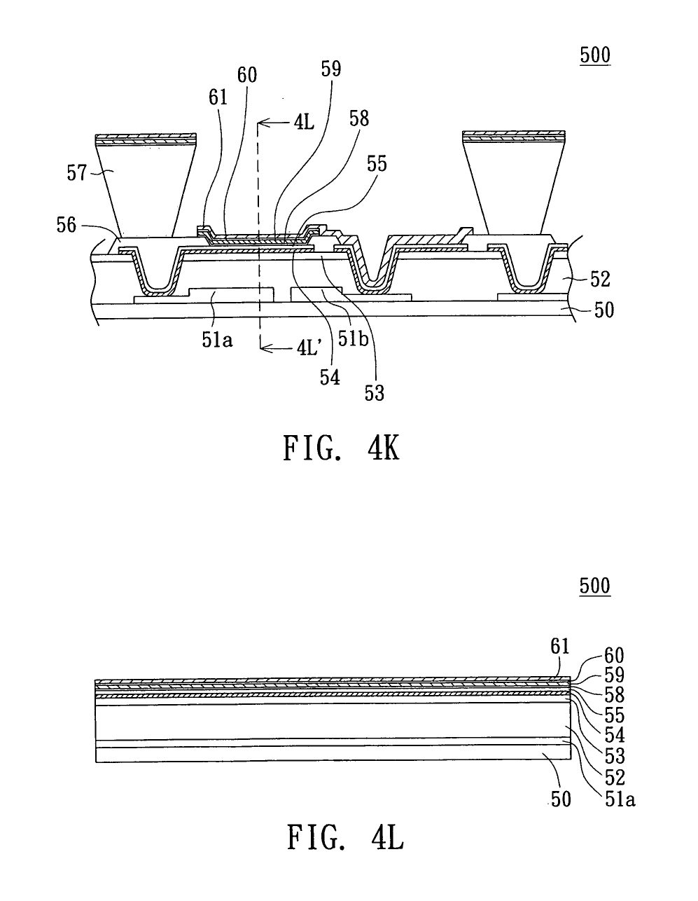

Refer now to FIGS. 4A-4K, which are diagrams illustrating a method for fabricating OELDs according to a specific embodiment of the invention. The method for fabricating the OELD 500 (FIGS. 4K-4L) includes following steps. At first, a plurality of thin film transistors (TFT) are formed on the substrate 50. Only two TFTs, i.e., 51a and 51b are shown in FIG. 4A. Next, an insulating layer 52 having a contact hole 52a is formed on the substrate 50, and covers the TFTs 51a and 51b as shown in FIG. 4B. One end of the TFT 51a, such as the drain electrode, is exposed through the contact hole 52a. The insulating layer 52 is made of an organic material, preferably a macromolecular organic material, such as PL402 resin acrylic manufactured by Japan Synthetic Rubber (JSR). Then, an adhesive layer 53 is formed on the insulating layer 52 as shown in FIG. 4C. The adhesive layer 53 is preferably an indium tin oxide (ITO) layer to improve the adherence of the insulating layer 52 to the subsequent reflective metal layer 54. Afterward, the reflective metal layer 54 is formed on the adhesive layer 53, and electrically connected to the exposed portion, i.e., the drain electrode, of the thin film transistor 51a, as shown in FIG. 4D. For example, the reflective metal layer 54 comprises aluminum (Al) or silver (Ag), and the thickness of the reflective metal layer 54 is more than 500 angstroms (A) to achieve better reflectivity. Then, as shown in FIG. 4E, a transparent conductive layer 55, such as indium tin oxide (ITO) or indium zinc oxide (IZO), as a main part of an electrode, such as an anode, is formed on and electrically connected to the reflective metal layer 54.

Next, a partition insulating layer 56 is formed on a part of the transparent conductive layer 55 as shown in FIG. 4F, by the following steps. At first, an insulating layer covers the transparent conductive layer 55, and then a first photoresist layer is formed thereon. Then, the first photoresist layer is patterned as a shielding mask, and the insulating layer is patterned accordingly to form the partition insulating layer 56. At last, the first photoresist layer is removed by a stripper, such as organic or inorganic alkali, to expose the partition insulating layer. Alternatively, a photosensitive resin material could also be used to form the partition insulating layer. The photosensitive resin is spread on the transparent conductive layer 55, and patterned by regular exposure and development processes to indirectly form the partition insulating layer 56.

In FIG. 4G, a partition rib 57 is formed on the partition insulating layer 56 by the following steps. At first, an insulating layer is deposited on the partition insulating layer 56, and a second photoresist layer is further spread thereon. Then, the second photoresist layer is patterned to provide a shielding mask, and the insulating layer is patterned accordingly to form the partition rib 27. At last, the second photoresist layer is removed by a stripper, such as organic or inorganic alkali, to expose the partition rib. Alternatively, a photosensitive resin material could also be used to form the partition rib. The photosensitive resin is spread on the transparent conductive layer 55, and patterned by regular exposure and development processes to indirectly form the partition insulating layer 56. Due to the protective cover provided by the transparent conductive layer 55, the reflective metal layer 54 will not be subject to and eroded by the stripper when the partition rib 57 and/or insulating layer 56 are formed. The material of the transparent conductive layer 55 can resist the stripper, such as alkali, which is used in the development step of the photolithography process, so that the transparent conductive layer 55 can protect the reflective metal layer 54 from being eroded by the stripper.

A first work function layer 58 is formed on the other part of the transparent conductive layer 55, which is not covered by the partition insulating layer 56, and adjacent to the partition insulating layer 56 and the partition rib 57, as shown in FIG. 4H. Alternatively, the first work function layer 58 could also be formed under the partition insulating layer 56 and the partition rib 57. Preferably, the first work function layer comprises Nickel (Ni), Nickel oxide (NiOₓ), carbon fluoride (CFₓ), hydrocarbon (CHₓ) or any combination thereof. Then, an organic emission layer 59 is formed on the first work function layer 58, as shown in FIG. 4I. Next, a second work function layer 60 is formed on the organic emission layer 59 as shown in FIG. 4J. The second work function layer 60 preferably comprises lithium fluoride (LiF). Finally, a second electrode, e. g, a cathode, 61 is formed on the second work function layer 60 as shown in FIG. 4K. The thickness of the cathode 61, preferably comprising aluminum (Al), is preferably about 100 angstroms, so that the emitted light can penetrate through the cathode 61. Alternatively, the second work function layer 60 can be omitted, and the cathode 61 comprises a calcium layer and a magnesium layer disposed thereon.

Referring to FIG. 4L, which is a cross-sectional view taken along line 4L-4L′ of FIG. 4K showing the organic electroluminescent device according to an embodiment. The organic electroluminescent device (OELD) 500 includes a substrate 50, a plurality of thin film transistors (TFTs) 51a, 51b (only 51a is visible in FIG. 4K), an insulating layer 52, an adhesive layer 53, a reflective metal layer 54, a transparent conductive layer 55, a first work function layer 58, an organic emission layer 59, a second work function layer 60 and a cathode 61. In the cross sectional view of FIG. 4L, the TFT 51a is positioned on substrate 50, and the insulating layer 52 covers the substrate 50 and TFT 51a. The adhesive layer 53 is used for bonding the insulating layer 52 and the reflective metal layer 54. The reflective metal layer 54 improves the conductivity between the transparent conductive layer 55, which is the main part of the anode, and the TFT 51a. The transparent conductive layer 55 and the first work function layer 58, as a complex anode of the OELD 500, are disposed on the reflective metal layer 54. The organic emission layer 59 is disposed on the first work function layer 58 to emit light when holes and electrons combine therein, and then the reflective metal layer 54 reflects the emitted light toward the electrode, e. g, cathode, 61, i.e., toward the viewer. The second work function layer 60 is disposed on the organic emission layer 59, and the cathode 61 is disposed on the second work function layer 60. The second work function layer 60 can enhance the work function of the cathode 61 to match with the anode, so that the luminescent efficiency of the OELD 500 can be improved.

According to the aforementioned description, the embodiments of the invention provide many advantages over conventional OELD technology. For example, the disclosed embodiments of the invention provide a transparent conductive layer on the reflective metal layer in order to prevent the reflective metal layer from being eroded by a stripper used during formation of the partition insulating layer and/or the partition rib, and/or to prevent the atoms in the reflective metal layer from diffusing to the adjacent work function layer. Also, the reflective metal layer can enhance the conductivity of the anode, which, in turn, improves the poor-conductivity problem long existing in the conventional OELDs. Thus, there is no need for the transparent conductive layer to be re-crystallized through an annealing process, so that the surface of the transparent conductive layer will be smooth and hardly deteriorate performance of the organic emission layer and the cathode.

While the invention has been described by way of example and in terms of the disclosed embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An organic electroluminescent device (OELD), comprising:
a reflective metal layer;
a transparent conductive layer formed above and electrically connected to the reflective metal layer to define a first electrode;
an organic emission layer formed above the transparent conductive layer; and
a second electrode formed above the organic emission layer.

2. The OELD according to claim 1, further comprising:
an insulating layer formed below the reflective metal layer; and
an adhesive layer formed between the reflective metal layer and the insulating layer.

3. The OELD according to claim 2, wherein the adhesive layer is an indium tin oxide (ITO) layer.

4. The OELD according to claim 2, wherein the insulating layer is an organic material layer.

5. The OELD according to claim 2, wherein the insulating layer has a contact hole, the OELD further comprising:
a substrate;
a thin film transistor (TFT) formed on the substrate and partially covered by the insulating layer, a terminal of the TFT being electrically connected to the reflective metal layer through the contact hole.

6. The OELD according to claim 5, wherein the transparent conductive layer is electrically connected to the TFT via the reflective metal layer.

7. The OELD according to claim 1, further comprising:
a first work function layer formed between the organic emission layer and the transparent conductive layer.

8. The OELD according to claim 7, wherein the reflective metal layer comprises aluminum (Al) or silver (Ag).

9. The OELD according to claim 8, wherein the first work function layer comprises at least one of Nickel (Ni), Nickel oxide (NiOₓ), carbon fluoride (CFₓ), hydrocarbon (CHₓ) and combinations thereof.

10. The OELD according to claim 7, further comprising:
a second work function layer formed between the second electrode and the organic emission layer.

11. The OELD according to claim 10, wherein the second work function layer comprises lithium fluoride (LiF).

12. The OELD according to claim 11, wherein the second electrode comprises aluminum (Al).

13. The OELD according to claim 1, wherein the second electrode comprises magnesium (Mg) or calcium (Ca).

14. The OELD according to claim 1, wherein the transparent conductive layer comprises indium tin oxide (ITO) or indium zinc oxide (IZO).

15. A method of fabricating an organic electroluminescent device (OELD), said method comprising:
forming a first electrode comprising a transparent conductive layer formed on and electrically connected to a reflective metal layer;
forming an organic emission layer above the transparent conductive layer; and
forming a second electrode above the organic emission layer.

16. The method according to claim 15, further comprising, prior to the step of forming the transparent conductive layer on the reflective metal layer:
forming a thin film transistor (TFT) on a substrate;
forming an insulating layer having a contact hole on the substrate and the TFT, the insulating layer partially covering the TFT and exposing a terminal of the TFT through the contact hole;
forming an adhesive layer on the insulating layer; and
forming the reflective metal layer on the adhesive layer, the reflective metal layer being electrically connected to the terminal of the TFT.

17. The method according to claim 15, wherein the step of forming the organic emission layer further comprises:
forming a partition insulating layer on a part of the transparent conductive layer;
forming a partition rib on the partition insulating layer;
forming a first work function layer on another part of the transparent conductive layer and adjacent the partition insulating layer and the partition rib; and
forming the organic emission layer on the first work function layer.

18. The method according to claim 15, wherein the reflective metal layer comprises aluminum (Al) or silver (Ag).

19. The method according to claim 17, wherein the first work function layer comprises at least one of Nickel (Ni), Nickel oxide (NiOₓ), carbon fluoride (CFₓ), hydrocarbon (CHₓ) and combinations thereof.

20. The method according to claim 17, wherein the step of forming the second electrode further comprises:
forming a second work function layer on the organic emission layer; and
forming the second electrode on the second work function layer.

21. The method according to claim 20, wherein the second work function layer is made of lithium fluoride (LiF).

22. The method according to claim 21, wherein the second electrode comprises aluminum (Al).

23. The method according to claim 15, wherein the second electrode comprises magnesium (Mg) or calcium (Ca).

24. The method according to claim 15, wherein the transparent conductive layer comprises indium tin oxide (ITO) or indium zinc oxide (IZO).

25. The method according to claim 15, wherein the first and second electrodes are an anode and a cathode, respectively.

26. The OELD according to claim 1, wherein the first and second electrodes are an anode and a cathode, respectively.

27. An organic electroluminescent display, comprising an organic electroluminescent device (OELD) which comprises:
a reflective metal layer;
a transparent conductive layer formed above and electrically connected to the reflective metal layer to define a first electrode;
an organic emission layer formed above the transparent conductive layer; and
a second electrode formed above the organic emission layer.
